(19) United States
(12) Patent Application Publication
(10) Pub. No.: US 2025/0273558 A1
(43) Pub. Date: Aug. 28, 2025

(54) METHODS FOR FORMING ASYMMETRICAL DIPOLES FOR CAPACITORS, RELATED DEVICES, AND RELATED SYSTEMS

(71) Applicant: ASM IP Holding B.V., Almere (NL)

(72) Inventors: Alessandra Leonhardt, Sipoo (FI); Fu Tang, Gilbert, AZ (US); Vivek Koladi Mootheri, Leuven (BE); Leo Lukose, Leuven (BE); Jerome Innocent, Bristol (GB); Michael Eugene Givens, Scottsdale, AZ (US); Andrea Illiberi, Leuven (BE); Rohit Abraham John, Chandler, AZ (US)

(21) Appl. No.: 19/058,966

(22) Filed: Feb. 20, 2025

Related U.S. Application Data
(60) Provisional application No. 63/556,672, filed on Feb. 22, 2024.

(51) Int. Cl. H01L 23/522; C23C 16/44; C23C 16/455; C23C 16/52; H01L 21/02; H10D 1/68

(52) U.S. Cl. CPC H01L 23/5223; C23C 16/4408; C23C 16/45553; C23C 16/52; H01L 21/0228; H10D 1/696

(57) ABSTRACT

Methods for manufacturing metal-insulator-metal (MIM) capacitors are disclosed. The methods include, forming a dielectric layer on at least part of a substrate, the dielectric layer being disposed between a first conductive layer and a second conductive layer, and forming at least one of a first dipole layer or a second dipole layer between the dielectric layer and one or more of the conductive layers. The disclosed first dipole layer and/or the second dipole layer are configured to create an asymmetric charge distribution across the dielectric layer. Systems constructed and arranged for manufacturing MIM capacitors are also disclosed.

### CROSS-REFERENCE TO RELATED APPLICATION(S)

This Application claims the benefit of U.S. Provisional Application 63/556,672 filed on Feb. 22, 2024, the entire contents of which are incorporated herein by reference.

### FIELD

The present disclosure generally relates to the field of semiconductor devices. More particularly, it relates to a metal-insulator-metal capacitor comprising a first conductive layer, a second conductive layer, a dielectric layer, and at least one dipole layer configured to create an asymmetric charge distribution across the dielectric layer, and methods and systems for producing the same.

### BACKGROUND OF THE DISCLOSURE

Modern integrated circuits are continuously scaled down to increase the number of components on a single chip. One such component is the Metal-Insulator-Metal (MIM) capacitor, widely used in various applications, including energy storage, analogue circuits, and radio frequency (RF) devices. The primary purpose of an MIM capacitor is to store electric charge, expressed as the capacitance value of the device. However, the trend towards increased miniaturization poses practical challenges in maintaining reasonable capacitance levels within confined spaces, leading to charge leakage between electronic components.

As capacitance is directly proportional to the dielectric constant of the insulating material placed between the metal plates of the MIM capacitor, high dielectric constant insulators (high-k value) with low charge leakage are needed for next-generation logic and memory applications. However, MIM capacitors comprising high-k materials may exhibit non-linear Capacitance-Voltage (CV) behavior, making the capacitance highly dependent on the applied (variable) voltage. Consequently, the capacitance of an MIM capacitor can be significantly lower at practical voltages or desired electric fields, leading to variations in performance, charge leakage, and premature device failure.

Therefore, a need exists to improve the manufacturing of MIM capacitors comprising high-k insulators or dielectrics to avoid the aforementioned problems, such as charge leakage, and obtain consistent and reliable electronic devices.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In general, the technology disclosed herein relates to the field of semiconductor devices, and more specifically to a method for manufacturing a metal-insulator-metal (MIM) capacitor used in the production of several electronic components such as integrated circuits and memory devices.

An aspect of the present disclosure relates to a method for manufacturing a metal-insulator-metal (MIM) capacitor, comprising the steps of: a) providing a substrate to a reaction chamber; b) forming a first conductive layer on at least a part of the substrate; c) optionally, forming a first dipole layer on the first conductive layer; d) forming a dielectric layer on the first conductive layer or on the optional first dipole layer; wherein the dielectric layer exhibits a capacitance peak at a characteristic voltage when a variable voltage is applied; e) optionally, forming a second dipole layer on the dielectric layer; and f) forming a second conductive layer on the dielectric layer or on the optional second dipole layer; provided that at least the first dipole layer and/or the second dipole layer are formed; wherein at least one of the first dipole layer and/or the second dipole layer is configured to create an asymmetric charge distribution across the dielectric layer, resulting in a shift of the capacitance peak of the dielectric layer to a target voltage different from said characteristic voltage.

One or more steps in the manufacturing of a MIM capacitor, as referred to herein, comprises the deposition of at least one thin dipole film arranged between the metal material and the insulator material of the capacitor. As a result, the capacitor as disclosed herein can comprise a metal-dipole-insulator-metal structure, a metal-insulator-dipole-metal structure, and/or a metal-dipole-insulator-dipole-metal structure.

In some examples, methods disclosed are employed to deposit a (permanent) dipole layer adjacent to the insulator or high-k dielectric material. This dipole layer can create a local electric field close to the high-k dielectric layer, shifting the capacitance peak of the dielectric from a characteristic voltage (for example, around ‘0 V’) to a target voltage (for example, around ‘+1V’ or ‘−1 V’) when an external electric field is applied.

In some examples, depending on the number of dipole layers, the capacitor can be engineered to provide a relatively smaller or a larger shift of the capacitance peak of the dielectric, offering a broad range of applications.

The high capacitance at a target voltage can significantly reduce the unintended loss of stored electric charge over time (i.e., charge leakage) when a variable external voltage is applied to a MIM capacitor, as defined herein, or an electronic device (e.g., a memory device) comprising such a MIM capacitor. This can be valuable in applications where a high voltage is applied, where a high resistance against charge mobility may be provided to trap or store electrical charges and avoid charge leakage.

An overview of various other aspects of the technology of the present disclosure is provided herein below, followed by a detailed description of specific embodiments. It should be understood that the objectives and advantages mentioned above apply equally to the various other aspects and features as disclosed herein.

Another aspect of the present disclosure relates to a system comprising: a reaction chamber constructed and arranged to hold a substrate; an electrode precursor vessel constructed and arranged to contain and evaporate one or more electrode precursor; a dipole precursor vessel constructed and arranged to contain and evaporate one or more dipole precursor; a dielectric precursor vessel constructed and arranged to contain and evaporate one or more dielectric precursor; an oxygen reactant vessel constructed and arranged to contain and evaporate one or more oxygen reactant; a nitrogen reactant vessel constructed and arranged to contain and evaporate one or more nitrogen reactant; a carbon reactant vessel constructed and arranged to contain and evaporate one or more carbon reactant; a controller, operatively connected to the electrode precursor vessel, the dipole precursor vessel, the dielectric precursor vessel, the oxygen reactant vessel, the nitrogen reactant vessel, and the carbon reactant vessel; wherein the controller is configured to control the introduction of the one or more electrode precursor, the one or more dipole precursor, the one or more dielectric precursor, the one or more oxygen reactant, the one or more nitrogen reactant, and the one or more carbon reactant into the reaction chamber during one or more cycles, wherein, as a result of the cycles, a Metal-Insulator-Metal (MIM) capacitor is formed comprising a dielectric layer with a capacitance peak at a characteristic voltage when a variable voltage is applied; and wherein the MIM capacitor further comprises at least one dipole layer configured to create an asymmetric charge distribution across the dielectric layer, resulting in a shift of the capacitance peak to a target voltage different from the characteristic voltage.

In some embodiments, the system as disclosed herein is configured to form a metal-insulator-metal (MIM) capacitor by means of a method as disclosed herein.

Another aspect of the present disclosure relates to a metal-insulator-metal (MIM) capacitor, comprising: a substrate; a first conductive layer and a second conductive layer; a dielectric layer, arranged between the first conductive layer and the second conductive layer; at least one dipole layer arranged between the first conductive layer and the dielectric layer, between the dielectric layer and the second conductive layer, or at least one dipole layer arranged between the first conductive layer and the dielectric layer and between the dielectric layer and the second conductive layer, or a combination thereof; and wherein the dielectric layer exhibits a capacitance peak at a characteristic voltage when a variable voltage is applied; wherein the at least one dipole layer is configured to create an asymmetric charge distribution across the dielectric layer, resulting in a shift of the capacitance peak to a target voltage different from the characteristic voltage.

In some embodiments, the MIM capacitor as disclosed herein is formed by means of a method as disclosed herein.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 describes an exemplary embodiment of a method for manufacturing a metal-insulator-metal (MIM) capacitor as disclosed herein.

FIG. 2 describes another exemplary embodiment of a method for manufacturing a metal-insulator-metal (MIM) capacitor as disclosed herein.

FIG. 3 describes another exemplary embodiment of a method for manufacturing a metal-insulator-metal (MIM) capacitor as disclosed herein.

FIG. 4 schematically shows an exemplary MIM capacitor of the disclosure.

FIG. 5 schematically shows another exemplary MIM capacitor of the disclosure comprising a substrate, a first conductive layer, a dielectric layer, a dipole layer, and a second conductive layer.

FIG. 6 schematically shows another exemplary MIM capacitor of the disclosure comprising a substrate, a first conductive layer, a dipole layer, a dielectric layer, a dipole layer, and a second conductive layer.

FIG. 7 schematically illustrates a system (700) in accordance with yet additional exemplary embodiments of the disclosure.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure disclosed should not be limited by the particular disclosed embodiments described below.

In the following detailed description, the technology underlying the present disclosure will be described by means of various aspects thereof. It will be readily understood that the aspects of the present disclosure, as generally described herein, and illustrated in the figures, can be arranged, substituted, combined, and designed in a wide variety of different configurations, all of which are explicitly contemplated and make part of this disclosure. This description is meant to aid the reader in understanding the technological concepts more easily, but it is not meant to limit the scope of the present disclosure.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” as used herein are synonymous with “including”, “includes” or “containing”, “contains”, and are inclusive or open-ended and do not exclude additional, non-recited members, elements, or method steps. The terms “comprising”, “comprises” and “comprised of” when referring to recited members, elements or method steps also include embodiments which “consist of” the recited members, elements, or method steps. The singular forms “a”, “an”, and “the” include both singular and plural referents unless the context clearly dictates otherwise.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, particularly a compound that constitutes a film matrix or a main skeleton of a film; the term “reactant” can be used interchangeably with the term precursor.

In the present description, technology is described by means of which a MIM capacitor is produced that is suitable for the manufacturing of memory devices. More specifically, various embodiments of the present disclosure relate to a thin-film deposition method for the manufacturing of a metal-insulator-metal (MIM) capacitor, comprising the steps of: a) providing a substrate to a reaction chamber; b) forming a first conductive layer on at least a part of the substrate; c) optionally, forming a first dipole layer on the first conductive layer; d) forming a dielectric layer on the first conductive layer or on the optional first dipole layer; wherein the dielectric layer exhibits a capacitance peak at a characteristic voltage when a variable voltage is applied; e) optionally, forming a second dipole layer on the dielectric layer; and f) forming a second conductive layer on the dielectric layer or on the optional second dipole layer; provided that at least the first dipole layer and/or the second dipole layer are formed; wherein at least one of the first dipole layer and/or the second dipole layer is configured to create an asymmetric charge distribution across the dielectric layer, resulting in a shift of the capacitance peak of the dielectric layer to a target voltage different from said characteristic voltage.

“Metal-insulator-metal (MIM) capacitors” typically comprise two metal electrodes or conductive layers that are separated by an insulating dielectric layer. This configuration enables the capacitor to store electrical charge in response to an applied voltage and effectively encode binary data states. When a voltage is applied across the electrodes, charge accumulates at the metal-insulator interfaces, creating distinct charge levels that represent ‘0’ or ‘1’ data bits. Hence, even when the power is removed (i.e., no external voltage is applied), data remains stored in the form of these charges. The ability of the MIM capacitor to store and retain charges plays a crucial role in achieving reliable data storage and memory operation.

The present disclosure provides MIM capacitors that comprise at least one dipole layer. The terms “first” and “second” dipole layer are used to indicate the position or arrangement of the respective dipole layer(s) in the stack of material layers that may form the MIM capacitor. In some embodiments, the manufactured MIM capacitor comprises a first dipole layer on the first conductive layer. In some embodiments, the manufactured MIM capacitor comprises a second dipole layer on the dielectric layer. In some embodiments, the manufactured MIM capacitor comprises a first dipole layer on the first conductive layer and a second dipole layer on the dielectric layer. Advantageously, the deposition of a thin dipole film at the metal-insulator interface may significantly improve the charge retention of the MIM capacitor, as further described herein, even when applying a high external voltage and/or using a thin dielectric layer.

The method disclosed herein relates to the formation of thin films or layers with specific electronic properties. A “film” or “layer,” as referred to herein, can encompass any continuous or non-continuous structure and material, including any material deposited by the methods disclosed herein. For example, a film and/or layer can include two-dimensional materials, three-dimensional materials, nanoparticles, or even partial or full molecular layers or partial or full atomic layers or clusters of atoms and/or molecules, or layers consisting of isolated atoms and/or molecules. A film or layer may comprise material or a layer with pinholes, which may be continuous or non-continuous.

The thin films or layers, as disclosed herein, can be formed, or deposited on the surface of a substrate. As used herein, the term “substrate” can refer to any underlying material or materials that can be used to form, or upon which, a device, a circuit, or a film can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes.

A substrate can comprise a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or (high-k) dielectric material layer overlying at least a portion of the bulk semiconductor material. In particular embodiments, the substrate may comprise silicon, silicon germanium, silicon oxide, gallium arsenide, gallium nitride or silicon carbide.

A continuous substrate may extend beyond the bounds of a process/reaction chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet or a flexible material. Continuous substrates may also comprise carriers or sheets upon which non-continuous substrates are mounted.

The MIM capacitor disclosed herein may be suitable for the manufacturing of a memory device. The term “memory device,” as used herein, refers to an electronic component designed to store, retain, and retrieve digital information. It may employ various physical mechanisms known in the art to represent and store data in a manner that allows for subsequent access and manipulation. Memory devices are integral components of computing systems and electronic devices, facilitating tasks such as data storage, retrieval, processing, and transfer. In the context of memory devices, MIM capacitors are important components for data storage and retrieval. The method disclosed herein is particularly suitable for producing MIM capacitors having a high charge retention and fast charge release, thus resulting in memory devices with more reliable data storage and retrieval.

In some examples, the formation of a MIM capacitor comprising a first dipole layer and/or a second dipole layer as described herein may relate to a cyclical deposition process, such as an atomic layer deposition (ALD) process or a cyclical chemical vapor deposition (CVD) process. In some embodiments, the method as disclosed herein may be an atomic layer deposition (ALD) method. In contrast to sputtering techniques commonly used within the state of the art for deposition of thin films and layers in various semiconductor and memory element manufacturing processes, atomic layer deposition may provide more uniform deposition across the surface of a substrate and improved material quality.

The cyclical deposition process may comprise one or more cycles. In particular embodiments, the method as disclosed herein provides that the formation of the first conductive layer, the first dipole layer, the dielectric layer, the second dipole layer, and/or the second conductive layer may each independently comprise one or more cycles; wherein each cycle may comprise one or more precursor and/or one or more reactant pulse.

As used herein, the term “deposition” or “cyclic deposition” or “cyclic deposition process” or “cyclical deposition process” refers to a sequential introduction of precursors (and/or reactants) into a reaction chamber to deposit a layer or film over a substrate and includes processing techniques such as atomic layer deposition (ALD), cyclical chemical vapor deposition (cyclical CVD), and hybrid cyclical deposition processes that include an ALD component and a cyclical CVD component. Typically, one deposition cycle may form a film or layer of about 0.10 nm. However, the experimental thickness may vary depending on the amount and type of cycles and available reaction sites on the substrate.

In some embodiments, the first conductive layer and second conductive layer may each independently have an average thickness of between 0.1 nm and 30.0 nm, or between 0.1 nm and 20.0 nm, preferably between 0.5 nm and 20.0 nm, or between 1.0 nm and 20.0 nm, or between 1.0 nm and 15.0 nm, or more preferably between 1.0 nm and 10.0 nm, even more preferably between 1.0 nm and 5.0 nm.

In some embodiments, the dielectric layer may have an average thickness of between 0.1 nm and 30.0 nm, or between 0.1 nm and 20.0 nm, preferably between 0.5 nm and 20.0 nm, or between 1.0 nm and 20.0 nm, or between 1.0 nm and 15.0 nm, or more preferably between 1.0 nm and 10.0 nm, even more preferably between 1.0 nm and 5.0 nm.

In some embodiments, the first dipole layer and the second dipole layer may each independently have an average thickness of at least 0.01 nm to at most 3.0 nm, or at least 0.01 nm to at most 2.5 nm, or at least 0.01 nm to at most 2.0 nm, or at least 0.01 nm to at most 1.5 nm, preferably at least 0.01 nm to at most 1.0 nm, or at least 0.01 nm to at most 0.9 nm, or at least 0.01 nm to at most 0.8 nm, or at least 0.01 nm to at most 0.7 nm, or at least 0.01 nm to at most 0.5 nm, or at least 0.01 nm to at most 0.4 nm, or at least 0.01 nm to at most 0.3 nm, or at least 0.01 nm to at most 0.2 nm, more preferably at least 0.01 nm to at most 0.1 nm.

An exemplary advantage of the methods disclosed herein is that they methods may allow the deposition of one or more dipole layers, such as a thin first dipole layer and/or a thin second dipole layer, which may decrease charge leakage across the insulating dielectric film without significantly changing the effective thickness of the dielectric layer. Even at small scales, the one or more dipole layers as defined herein may provide for a shift in the capacitance peak of the dielectric layer to a specific voltage, resulting in improved performance of the MIM capacitor. Moreover, thorough experimentation has shown that the amount of dipole material may be minimized, hence providing for a more cost-effective production method of MIM capacitors with high charge retention.

In some embodiments, the first dipole layer and/or the second dipole layer may have a growth rate of 0.01 nm or less per cycle of precursor(s)/reactive gas(es), and purge (e.g., inert carrier) gas(es).

The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

In ALD processes, during each cycle, generally a precursor is introduced to a reaction chamber and is chemisorbed to a deposition surface (e.g., a substrate surface that can include a previously deposited material from a previous ALD cycle or other material), thereby forming a material, e.g. about a monolayer or sub-monolayer of material, or several monolayers of material, or a plurality of monolayers of material, which does not readily react with additional precursor (i.e., a self-limiting reaction). Thereafter, in some cases, a reactant (e.g., another precursor or reaction gas) may be introduced into the process chamber for use in converting the chemisorbed precursor to the desired material on the deposition surface. The reactant can be capable of further reaction with the precursor. It should be noted that, as used herein, ALD processes are not necessarily comprised of a sequence of self-limiting surface reactions.

Optionally, purging steps can be utilized during one or more repetitions, e.g., during each deposition step, to remove any excess precursor from the process chamber and/or remove any excess reactant and/or reaction byproducts from the reaction chamber. As used herein, the term “purge” may refer to a procedure in which an inert or substantially inert gas is provided to a reaction chamber in between two pulses of gasses that react with each other. For example, a purge, e.g., using an inert gas such as a noble gas, may be provided between a precursor pulse and a reactant pulse, thus avoiding, or at least minimizing gas phase interactions between the precursor and the reactant.

In some embodiment, the cyclical deposition processes as disclosed herein can be a thermal deposition process. In other words, in some embodiments, none of the pulses or purges in the cyclical deposition processes employ a plasma. In the case of thermal cyclical deposition processes, a duration of the step of providing the hafnium precursor and/or zirconium precursor to the reaction chamber, a duration of the step of providing the reactant to the reaction chamber, and/or a duration of the step of providing the germanium dopant to the reaction chamber can be relatively long to allow the precursors, reactants, and/or dopants containing gas to react with a surface of the substrate. For example, the duration can be greater than or equal to 5 seconds or greater than or equal to 10 seconds or between about 5 and 10 seconds.

In some embodiments, the cyclical deposition processes disclosed employs a plasma-enhanced deposition technology. For example, the cyclical deposition processes may comprise a plasma-enhanced atomic layer deposition processes and/or a plasma-enhanced chemical vapor deposition process. In such a case, any one of the pulses in the cyclical depositing process may comprise generating a plasma in the reaction chamber.

In some embodiments, the method as disclosed herein may be a continuous vacuum deposition process. In the context of a continuous vacuum deposition process, a material is deposited onto a substrate in a reaction chamber without the introduction of atmospheric air or any interruptions that would break the controlled vacuum environment. This process involves maintaining a consistent vacuum pressure within the reaction chamber. In particular embodiments, the method as disclosed herein provides that the MIM capacitor is formed without any intervening vacuum break. An advantage of avoiding an intervening vacuum break is that it prevents the need for repeated evacuations and purges that are common in traditional batch deposition methods.

In some embodiments, the method as disclosed herein provides that the formation of the first conductive layer, the first dipole layer, the dielectric layer, the second dipole layer, and/or the second conductive layer may each independently comprise at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 1000 cycles, or from at least 2 cycles to at most 100 cycles, or from at least 5 cycles to at most 50 cycles.

A cycle may comprise one or more pulses. In some embodiments, at least one pulse involves a self-limiting surface reaction. In some embodiments, all pulses involve a self-limiting surface reaction. In the context ALD, a self-limiting surface reaction refers to a chemical reaction that automatically halts or slows down once a certain threshold or coverage is reached on a surface, for instance, once a complete monolayer or sub-monolayer is formed the reactions stops by preventing further reaction with additional precursor. In some embodiments, a cycle comprises one or more precursor pulse and/or one or more reactant pulse.

In some embodiments, the one or more precursor pulse lasts from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

In some embodiments, the one or more reactant pulse lasts from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

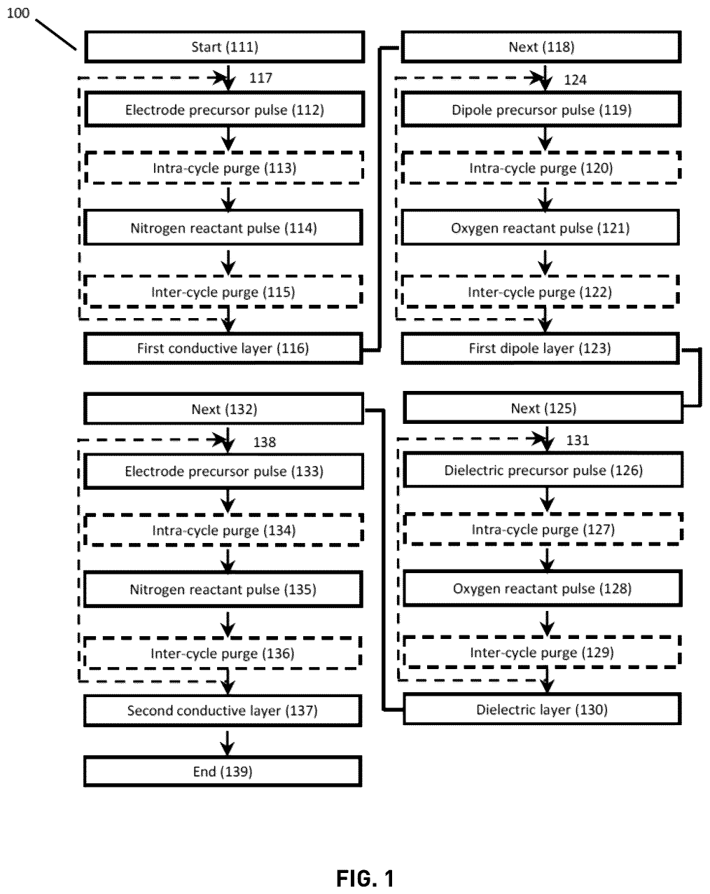

FIG. 1. Illustrates an exemplary method for manufacturing a MIM capacitor (100). The method starts (111) after a substrate has been provided to a reaction chamber. The cyclical deposition process comprises, contacting one or more electrode precursor(s) with at least a part of the substrate in an electrode precursor pulse (112). Optionally, the reaction chamber is purged (113) after the electrode precursor pulse.

In some embodiments, one or more nitrogen reactant(s) are provided to the reaction chamber in a nitrogen reactant pulse (114). Optionally, the reaction chamber can be purged (115) after the nitrogen reactant pulse. The electrode precursor pulse (112), the nitrogen reactant pulse (114), and the optional purges (113,115) can be repeated (117) any number of times to obtain desired thickness of a first conductive layer (116).

The cyclical deposition process can continue (118) by contacting one or more dipole precursor(s) with the formed first conductive layer (116) in a dipole precursor pulse (119). Optionally, the reaction chamber is purged (120) after the dipole precursor pulse. Then, one or more oxygen reactant(s) can be provided to the reaction chamber in an oxygen reactant pulse (121). Optionally, the reaction chamber can be purged (122) after the oxygen reactant pulse. The sequence of the dipole precursor pulse (119), the oxygen reactant pulse (121) and the optional purges (120,122) can be repeated (124) any number of times to achieve a desired thickness of the first dipole layer (123).

The cyclical deposition process can continue (125) by contacting one or more dielectric precursor(s) with the formed first dipole layer (123) in a dielectric precursor pulse (126). Optionally, the reaction chamber is purged (127) after the dielectric precursor pulse. Then, one or more oxygen reactant(s) is provided to the reaction chamber in an oxygen reactant pulse (128). Optionally, the reaction chamber can be purged (129) after the oxygen reactant pulse. The sequence of the dielectric precursor pulse (126), the oxygen reactant pulse (128) and the optional purges (127,129) can be repeated (131) any number of times to obtain a desired thickness of a dielectric layer (130).

The cyclical deposition process can continue (132) by contacting one or more electrode precursor(s) with the formed dielectric layer (130) in an electrode precursor pulse (133). Optionally, the reaction chamber is purged (134) after the electrode precursor pulse. Then, one or more nitrogen reactant(s) is provided to the reaction chamber in a nitrogen reactant pulse (135). Optionally, the reaction chamber can be purged (136) after the nitrogen reactant pulse. The sequence of electrode precursor pulse (133), the nitrogen reactant pulse (135) and the optional purges (134,136) can be repeated (138) any number of times to obtain a desired thickness of a second conductive layer (137).

The method can conclude (139) when the desired stack of layers is formed based on any combination of the aforementioned steps. Once the method has ended, the substrate can be subjected to additional processes known in the art for forming a device structure and/or device.

Optionally, nitrogen reactant pulse (114) and nitrogen reactant pulse (135) as described herein may independently be replaced with a carbon reactant pulse, wherein one or more carbon reactant(s) is provided to the reaction chamber.

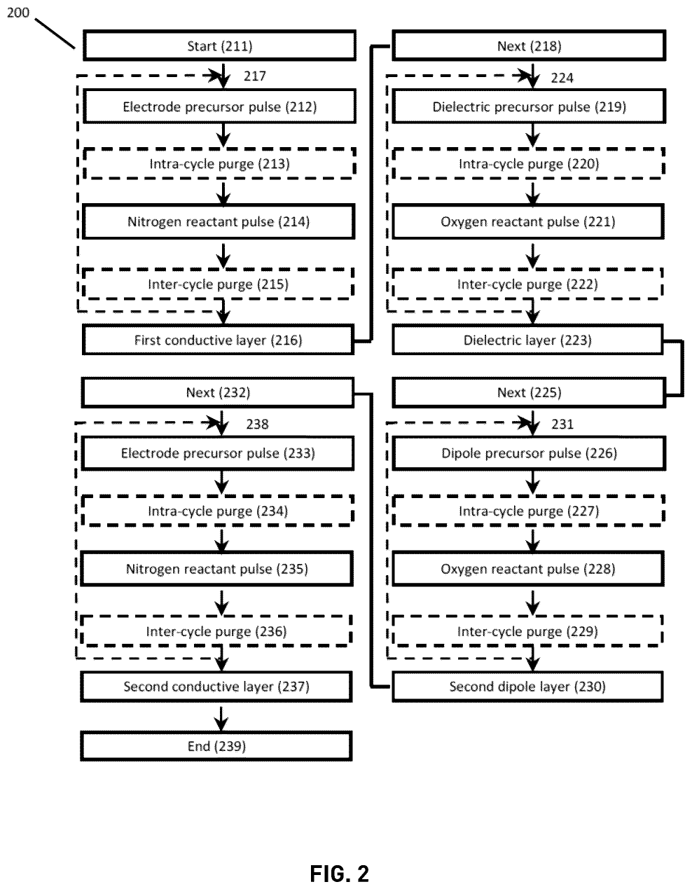

FIG. 2. Illustrates another method for manufacturing of a MIM capacitors (200). The method can begin (211) after a substrate has been provided to a reaction chamber. The cyclical deposition process comprises contacting one or more electrode precursor(s) with at least a part of the substrate in an electrode precursor pulse (212). Optionally, the reaction chamber is purged (213) after the electrode precursor pulse. Then, one or more nitrogen reactant(s) is provided to the reaction chamber in a nitrogen reactant pulse (214). Optionally, the reaction chamber can be purged (215) after the nitrogen reactant pulse. The sequence of the electrode precursor pulse (212), the nitrogen reactant pulse (214) and the optional purges (213,215) can be repeated (217) any number of times to obtain a desired thickness of a first conductive layer (216).

Next (218), the cyclical deposition process continues by contacting one or more dielectric precursor(s) with the formed first conductive layer (216) in a dielectric precursor pulse (219). Optionally, the reaction chamber is purged (220) after the dielectric precursor pulse. Then, one or more oxygen reactant(s) is provided to the reaction chamber in an oxygen reactant pulse (221). Optionally, the reaction chamber can be purged (222) after the oxygen reactant pulse. The sequence of the dielectric precursor pulse (219), the oxygen reactant pulse (221) and the optional purges (220,222) can be repeated (224) any number of times to obtain a desired thickness of a dielectric layer (223).

Next (225), the cyclical deposition process continues by contacting one or more dipole precursor(s) with the formed dielectric layer (223) in a dipole precursor pulse (226). Optionally, the reaction chamber is purged (227) after the dipole precursor pulse. Then, one or more oxygen reactant(s) is provided to the reaction chamber in an oxygen reactant pulse (228). Optionally, the reaction chamber can be purged (229) after the oxygen reactant pulse. The sequence of the dipole precursor pulse (226), the oxygen reactant pulse (228) and the optional purges (227,229) can be repeated (231) any number of times to obtain a desired thickness of a second dipole layer (230).

Next (232), the cyclical deposition process continues by contacting one or more electrode precursor(s) with the formed second dipole layer (230) in an electrode precursor pulse (233). Optionally, the reaction chamber is purged (234) after the electrode precursor pulse. Then, one or more nitrogen reactant(s) is provided to the reaction chamber in a nitrogen reactant pulse (235). Optionally, the reaction chamber can be purged (236) after the nitrogen reactant pulse. The sequence of the electrode precursor pulse (233), the nitrogen reactant pulse (235) and the optional purges (234,236) can be repeated (238) any number of times to obtain a desired thickness of a second conductive layer (237).

The method concludes (239) when the desired stack of layers is formed based on any combination of the aforementioned steps. Once the method has ended, the substrate can be subjected to additional processes known in the art for forming a device structure and/or device.

Optionally, nitrogen reactant pulse (214) and nitrogen reactant pulse (235) as described herein may independently be replaced with a carbon reactant pulse, wherein one or more carbon reactant(s) is provided to the reaction chamber.

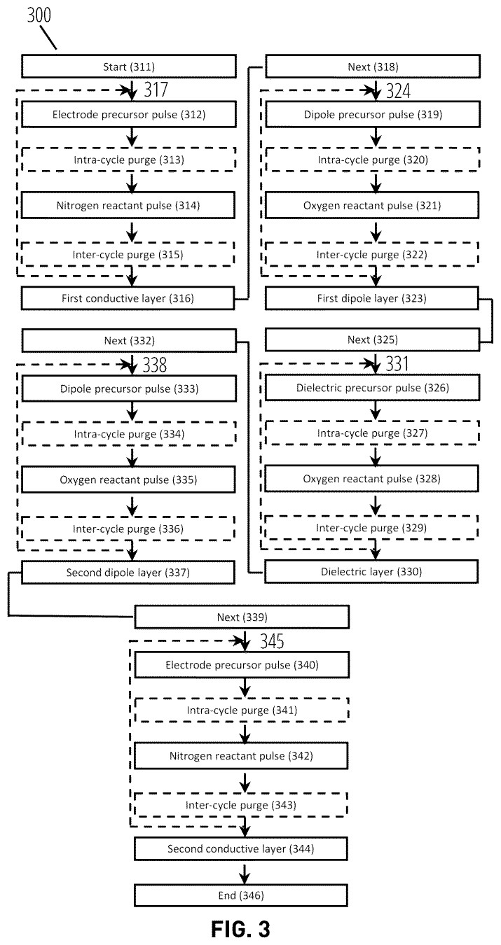

FIG. 3. Illustrates an additional method for manufacturing a MIM capacitor (300). The method starts (311) after a substrate has been provided to a reaction chamber. The cyclical deposition process comprises contacting one or more electrode precursor(s) with at least a part of the substrate in an electrode precursor pulse (312). Optionally, the reaction chamber is purged (313) after the electrode precursor pulse. Then, one or more nitrogen reactant(s) is provided to the reaction chamber in a nitrogen reactant pulse (314). Optionally, the reaction chamber can be purged (315) after the nitrogen reactant pulse. The sequence of the electrode precursor pulse (312), the nitrogen reactant pulse (314) and the optional purges (313,315) can be repeated (317) any number of times to obtain a desired thickness of a first conductive layer (316).

Next (318), the cyclical deposition process continues by contacting one or more dipole precursor(s) with the formed first conductive layer (316) in a dipole precursor pulse (319). Optionally, the reaction chamber is purged (320) after the dipole precursor pulse. Then, one or more oxygen reactant is provided to the reaction chamber in an oxygen reactant pulse (321). Optionally, the reaction chamber can be purged (322) after the oxygen reactant pulse. The sequence of the dipole precursor pulse (319), the oxygen reactant pulse (321) and the optional purges (320,322) can be repeated (324) any number of times to obtain a desired thickness of a first dipole layer (323).

Next (325), the cyclical deposition process continues by contacting one or more dielectric precursor(s) with the formed first dipole layer (323) in a dielectric precursor pulse (326). Optionally, the reaction chamber is purged (327) after the dielectric precursor pulse. Then, one or more oxygen reactant(s) is provided to the reaction chamber in an oxygen reactant pulse (328). Optionally, the reaction chamber can be purged (329) after the oxygen reactant pulse. The sequence of the dielectric precursor pulse (326), the oxygen reactant pulse (328) and the optional purges (327,329) can be repeated (331) any number of times to obtain a desired thickness of a dielectric layer (330).

Next (332), the cyclical deposition process continues by contacting one or more dipole precursor(s) with the formed dielectric layer (330) in a dipole pulse (333). Optionally, the reaction chamber is purged (334) after the dipole precursor pulse. Then, one or more oxygen reactant(s) is provided to the reaction chamber in an oxygen reactant pulse (335). Optionally, the reaction chamber can be purged (336) after the oxygen reactant pulse. The sequence of the dipole precursor pulse (333), the oxygen reactant pulse (335) and the optional purges (334,336) can be repeated (338) any number of times to obtain a desired thickness of a second dipole layer (337).

Next (339), the cyclical deposition process continues by contacting one or more electrode precursor(s) with the formed second dipole layer (337) in an electrode precursor pulse (340). Optionally, the reaction chamber is purged (341) after the electrode precursor pulse. Then, one or more nitrogen reactant(s) is provided to the reaction chamber in a nitrogen reactant pulse (342). Optionally, the reaction chamber can be purged (343) after the nitrogen reactant pulse. The sequence of the electrode precursor pulse (340), the nitrogen reactant pulse (342) and the optional purges (341,343) can be repeated (345) any number of times to obtain a desired thickness of a second conductive layer (344).

The method concludes (346) when the desired stack of layers is formed based on any combination of the aforementioned steps. Once the method has ended, the substrate can be subjected to additional processes known in the art for forming a device structure and/or device.

Optionally, nitrogen reactant pulse (314) and nitrogen reactant pulse (342) as described herein may independently be replaced with a carbon reactant pulse, wherein one or more carbon reactant(s) is provided to the reaction chamber.

In the present disclosure, the at least one dipole layer, formed by the methods as disclosed herein, can be configured to create an asymmetric charge distribution across the dielectric layer of the MIM capacitor. This at least one dipole layer may be the first dipole layer and/or the second dipole layer of the MIM capacitor. As used herein, an asymmetric charge distribution can refer to an uneven distribution of electric charge on either side of the dielectric layer (i.e., at the metal-insulator interface and/or insulator-metal interface). This configuration may result in a built-in electric field that may be stronger on one side or interface of the dielectric compared to the other.

Conventionally, asymmetric charge distributions are controlled and minimized in the state of the art to ensure proper functioning of the capacitor and avoid unwanted effects such as dielectric breakdown. In contrast, however, the present disclosure seeks to intentionally provide at least one dipole layer that creates an asymmetric charge distribution across the dielectric layer of a MIM capacitor. This asymmetry may shift the capacitance peak of the dielectric to a desired voltage. This has the advantage that the dielectric material may provide a high (maximum) capacitance when subjected to a variable voltage, resulting in improved charge retention and reduced charge leakage. Moreover, the possibility to strategically position of the one or more thin dipole film provides for improved flexibility in MIM capacitor design.

The “desired voltage” or “target voltage” as used herein is application dependent. For example, a high (maximum) capacitance peak may be desirable at a voltage of −0.5 V, −1 V, 0.5 V, or 1 V. It is important to note that herein disclosed dipole layer is not limited to a specific target voltage and the herein provided target voltages are exemplary in nature.

In some embodiments, the formation of a first dipole layer at the interface of the first conductive layer and the dielectric layer provides a weak built-in electric field. In some embodiments, the formation of a second dipole layer at the interface of the dielectric layer and the second conductive layer provides a weak built-in electric field. In some embodiments, the formation of a first dipole layer at the interface of the first conductive layer and the dielectric layer and the formation of a second dipole layer at the interface of the dielectric layer and the second conductive layer provides a strong built-in electric field.

In some embodiments, the method as disclosed herein provides that the first dipole layer and the second dipole layer may each independently comprise an element selected from the group consisting of Sc, Y, Sr, Al, Si, Ga, Ge, In, Sn, La, and Ce. Dipole layers comprising the listed elements were found to improve charge retention of the dielectric layer at a target voltage.

In some embodiments, the method as disclosed herein provides that the first dipole layer and the second dipole layer may each independently comprise an oxide selected from the group consisting of Sc₂O₃, Y₂O₃, SrO, Al₂O₃, SiO₂, Ga₂O₃, GeO₂, In₂O₃, SnO₂, La₂O₃, and CeO₂. Dipole layers comprising the listed oxides were found to improve charge retention of the dielectric layer at a target voltage.

In some embodiments, the method as disclosed herein provides that the first dipole layer may be an n-type dipole layer, and the second dipole layer may be a p-type dipole layer. In particular embodiments, the method as disclosed herein provides that the first dipole layer may be a p-type dipole layer, and the second dipole layer may be an n-type dipole layer.

In some examples, suitable oxides for n-type dipoles may include Sc₂O₃, SrO, La₂O₃, Y₂O₃, and CeO₂, which may be deposited using a cyclical deposition process as defined herein.

In some examples, suitable oxides for p-type dipoles may include Al₂O₃, SiO₂, Ga₂O₃, GeO₂, In₂O₃, and SnO₂, which may be deposited using a cyclical deposition process as defined herein.

Advantageously, the use of opposite dipole layers (i.e., an n-type dipole layer and a p-type dipole layer) in the MIM capacitor may provide a significant difference in charge density across the dielectric layer, which may result in a large shift in the capacitance peak of the dielectric layer.

In particular embodiments, the method as disclosed herein provides that at least one of the first dipole layer and the second dipole layer may have a dielectric constant (k) value of at least 8.0, or at least 10.0, or at least 12.0, preferably at least 15.0, or at least 18.0, more preferably at least 20.0, or at least 25.0, or at least 30.0. A higher dielectric constant or capacitance of the dipole layer was found to increase the asymmetry in charge distribution (i.e., higher charge storage at the dipole layer) across the dielectric layer, resulting in a tunable shift of the capacitance peak.

In the present disclosure, the dielectric layer of the MIM capacitor formed by means of the method as disclosed herein has a (maximum) capacitance peak at a characteristic voltage. Preferably, the dielectric layer has a high capacitance to enable good charge storage. In particular embodiments, the method as disclosed herein provides that the dielectric layer may comprise a high k dielectric material with a dielectric constant (k) value of at least 8.0, or at least 10.0, or at least 12.0, or at least 15.0, or at least 20.0, or at least 22.0, or at least 25.0, or at least 30.0, or at least 35.0, preferably at least 40.0, more preferably at least 45.0.

In some embodiments, the method as disclosed herein provides that the high k dielectric material may comprise one or more oxide. The one or more oxide may be selected from the group consisting of hafnium zirconium oxide (HfZrO₂), aluminum oxide (Al₂O₃), yttrium oxide (Y₂O₃), tantalum oxide (Ta₂O₅), hafnium oxide (HfO₂), zirconium oxide (ZrO₂), lanthanum oxide (La₂O₃), niobium oxide (Nb₂O₅), and titanium oxide (TiO₂). The listed oxides are characterized by a dielectric constant (k value) higher than silicon oxide such as higher than about 7, which were found to provide a good balance between good charge retention and fast charge release.

In some embodiments, the method as disclosed herein provides that the dielectric layer may comprise a dopant selected from the group consisting of PH₃, PF₅, PCl₅, PBr₅, AsF₅, AsCl₅, AsBr₅, AsH₃, SbF₃, SbCl₃, SbBr₃, BF₃, BCl₃, BBr₃, B₂H₆, AlF₃, AlCl₃, AlBr₃, InF₃, InCl₃, and InBr₃. The introduction of a dopant may further improve the charge retention and release characteristics of the dielectric layer.

In some embodiments, the method as disclosed herein provides that at least one of the first dipole layer or at least one of the second dipole layer are formed, which may shift the capacitance peak of the dielectric layer to a target voltage by at least 10 mV, or at least 15 mV, or at least 30 mV, or at least 50 mV, or at least 100 mV, or at least 200 mV, or at least 500 mV.

In some embodiments, the method as disclosed herein provides that the first dipole layer and the second dipole layer are formed, which may shift the capacitance peak of the dielectric layer to a target voltage by at least 10 mV, or at least 15 mV, or at least 30 mV, or at least 50 mV, or at least 100 mV, or at least 200 mV, or at least 500 mV. Advantageously, the use of the first dipole layer and the second dipole layer may provide a larger shift in capacitance peak of the dielectric layer, when compared to using one dipole layer.

In some embodiments, the method as disclosed herein provides that the first conductive layer and the second conductive layer may each independently comprise an element selected from the group consisting of Mg, Ca, Cu, Sr, Ba, Al, Ga, In, Sc, Y, La, Ce, Pr, Nd, Pm, Sm, Eu, Gd, Tb, Dy, Ho, Er, Tm, Yb, Lu, Ti, Zr, Hf, V, Nb, Ta, Cr, Mo, Re, Ge, Sb, Zn, and W. The first conductive layer and the second conductive layer as described herein may also be referred as the “electrodes,” “metal electrodes” or “metal layer.”

In some embodiments, the method as disclosed herein provides that the first conductive layer and the second conductive layer may each independently comprise a metal carbide selected from the group consisting of LaC, YC, ErC, SmC, EuC, YbC, CeC, TiC, ZrC, HfC, VC, NbC, TaC, ScC, CrC, MoC, and WC. The listed metal carbides were found to be compatible with a range of dielectric materials, thermally stable, and chemically inert, which may contribute to the long-term reliability and stability of a MIM capacitor.

In some embodiments, the method as disclosed herein provides that the first conductive layer and the second conductive layer may each independently comprise a metal nitride selected from the group consisting of CuN, TiN, ZrN, HfN, VN, NbN, TaN, ScN, CrN, MoN, and WN. The listed metal nitrides were found to be compatible with a range of dielectric materials, thermally stable, and chemically inert, which may contribute to the long-term reliability and stability of a MIM capacitor.

The method as disclosed herein may be performed at different temperatures and/or pressures. In particular embodiments, the method as disclosed herein provides that the substrate may be heated to a temperature of at least about 80.0° C. to at most about 400.0° C., or at least about 100.0° C. to at most about 400.0° C., or at least about 125.0° C. to at most about 400.0° C., preferably at least about 150.0° C. to at most about 400.0° C., or at least about 175.0° C. to at most about 400.0° C., preferably at least about 200.0°° C. to at most about 400.0° C., or at least about 250.0° C. to at most about 400.0° C., or at least about 300.0° C. to at most about 400.0° C. The listed temperatures can decrease the time needed for material deposition, although lower or higher temperatures can be considered still.

In some embodiments, the method as disclosed herein provides that the pressure in the reaction chamber may be between about 0.1 Torr and about 100.0 Torr, or between about 0.5 Torr and about 100.0 Torr, or between about 1.0 Torr and about 100.0 Torr, or between about 2.0 Torr and about 100.0 Torr, or between about 5.0 Torr and about 100.0 Torr, or between about 5.0 Torr and about 80.0 Torr, or preferably between about 5.0 Torr and about 50.0 Torr, or between about 10.0 Torr and about 50.0 Torr. The listed pressures can decrease the time needed for material deposition, although lower or higher pressures can be considered still.

The MIM capacitor may be formed in any suitable reactor. Thus, in some embodiments, the MIM capacitor may be deposited in a cross-flow reactor. In some embodiments, the MIM capacitor may be deposited in a showerhead reactor. In some embodiments, the MIM capacitor may be deposited in a hot-wall reactor. In some embodiments, the MIM capacitor may be deposited in a cold-wall reactor. Doing so can advantageously enhance uniformity and/or repeatability of the deposition processes, in particular when forming one or more thin dipole layer(s) as described herein.

In some embodiments, the substrate may be subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

Another aspect of the present disclosure relates to a system comprising: a reaction chamber constructed and arranged to hold a substrate; an electrode precursor vessel constructed and arranged to contain and evaporate one or more electrode precursor; a dipole precursor vessel constructed and arranged to contain and evaporate one or more dipole precursor; a dielectric precursor vessel constructed and arranged to contain and evaporate one or more dielectric precursor; an oxygen reactant vessel constructed and arranged to contain and evaporate one or more oxygen reactant; a nitrogen reactant vessel constructed and arranged to contain and evaporate one or more nitrogen reactant; a carbon reactant vessel constructed and arranged to contain and evaporate one or more carbon reactant; a controller, operatively connected to the electrode precursor vessel, the dipole precursor vessel, the dielectric precursor vessel, the oxygen reactant vessel, the nitrogen reactant vessel, and the carbon reactant vessel; wherein the controller is configured to control the introduction of the one or more electrode precursor, the one or more dipole precursor, the one or more dielectric precursor, the one or more oxygen reactant, the one or more nitrogen reactant, and the one or more carbon reactant into the reaction chamber during one or more cycles, wherein, as a result of the cycles, a metal-insulator-metal (MIM) capacitor is formed comprising a dielectric layer with a capacitance peak at a characteristic voltage when a variable voltage is applied; and wherein the MIM capacitor further comprises at least one dipole layer configured to create an asymmetric charge distribution across the dielectric layer, resulting in a shift of the capacitance peak to a target voltage different from the characteristic voltage.

The system as disclosed herein can be configured to deposit one or more layers during said one or more cycles, thereby obtaining a MIM capacitor comprising a stack of layers deposited on a substrate as described herein.

In some embodiments, the stack of layers comprises a first conductive layer and a second conductive layer; a dielectric layer, arranged between the first conductive layer and the second conductive layer; and a dipole layer arranged between the first conductive layer and the dielectric layer.

In some embodiments, the stack of layers comprises a first conductive layer and a second conductive layer; a dielectric layer, arranged between the first conductive layer and the second conductive layer; and a dipole layer arranged between the dielectric layer and the second conductive layer.

In some embodiments, the stack of layers comprises a first conductive layer and a second conductive layer; a dielectric layer, arranged between the first conductive layer and the second conductive layer; and a dipole layer arranged between the first conductive layer and the dielectric layer and between the dielectric layer and the second conductive layer.

In some embodiments, deposition of the first conductive layer and second conductive layer comprises the execution of one or more deposition cycles, wherein a cycle comprises an electrode precursor pulse as described herein, wherein one or more electrode precursor is transferred from the electrode precursor vessel to the reaction chamber; and a nitrogen reactant pulse and/or carbon reactant pulse as described herein, wherein one or more nitrogen reactant or one or more carbon reactant is transferred from the nitrogen reactant vessel or carbon reactant vessel to the reaction chamber.

In some examples, the system as disclosed herein provides that the one or more electrode precursor may comprise one or more element selected from the group consisting of Mg, Ca, Cu, Sr, Ba, Al, Ga, In, Sc, Y, La, Ce, Pr, Nd, Pm, Sm, Eu, Gd, Tb, Dy, Ho, Er, Tm, Yb, Lu, Ti, Zr, Hf, V, Nb, Ta, Cr, Mo, Re, Ge, Sb, Zn, and W. The one or more electrode precursor may further comprise any suitable ligand that enables fast evaporation of the one or more electrode precursor. For instance, the one or more electrode precursor may further comprise one or more halogen selected from the group consisting of fluoro (F), chloro (Cl), bromo (Br), iodo (I), and combinations thereof.

In some embodiments, the one or more electrode precursor may be selected from the group consisting of MgCl₂, CaCl₂, CuCl₂, SrCl₂, BaCl₂, AlCl₃, GaCl₃, InCl₃, ScCl₃, YCl₃, LaCl₃, CeCl₃, PrCl₃, NdCl₃, PmCl₃, SmCl₃, EuCl₃, GdCl₃, TbCl₃, DyCl₃, HoCl₃, ErCl₃, TmCl₃, YbCl₃, LuCl₃, TiCl₄, ZrCl₄, HfCl₄, VCl₃, NbCl₃, TaCl₅, CrCl₃, MoCl₃, ReCl₃, GeCl₄, SbCl₃, ZnCl₂, WCl₆, MgBr₂, CaBr₂, CuBr₂, SrBr₂, BaBr₂, AlBr₃, GaBr₃, InBr₃, ScBr₃, YBr₃, LaBr₃, CeBr₃, PrBr₃, NdBr₃, PmBr₃, SmBr₃, EuBr₃, GdBr₃, TbBr₃, DyBr₃, HoBr₃, ErBr₃, TmBr₃, YbBr₃, LuBr₃, TiBr₄, ZrBr₄, HfBr₄, VBr₃, NbBr₃, TaBr₅, CrBr₃, MoBr₃, ReBr₃, GeBr₄, SbBr₃, ZnBr₂, WBr₆, MgI₂, CaI₂, CuI₂, SrI₂, BaI₂, AlI₃, GaI₃, InI₃, ScI₃, YI₃, LaI₃, CeI₃, PrI₃, NdI₃, PmI₃, SmI₃, EuI₃, GdI₃, TbI₃, DyI₃, HoI₃, ErI₃, TmI₃, YbI₃, LuI₃, TiI₄, ZrI₄, HfI₄, VI₃, NbI₃, TaI₅, CrI₃, MoI₃, ReI₃, GeI₄, SbI₃, ZnI₂, WI₆, and mixtures thereof.

In some examples, the system as disclosed herein provides that the one or more nitrogen reactant may be selected from the group consisting of ammonia (NH₃), diazene (N₂H₂), and hydrazine (N₂H₄).

In some examples, the system as disclosed herein provides that the one or more carbon reactant may be selected from the group consisting of alkyl halide and alkenyl halide.

The term “halo” or “halogen” as a group or part of a group is generic for fluoro (F), chloro (Cl), bromo (Br), iodo (I).

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₂₀alkyl”, as a group or part of a group, refers to a hydrocarbyl group of formula —CₙH₂ₙ₊₁ wherein n is a number ranging from 1 to 20. Thus, for example, “C₁₋₈alkyl” includes all linear or branched alkyl groups with between 1 and 8 carbon atoms, and thus includes methyl, ethyl, n-propyl, i-propyl, butyl and its isomers (e.g. n-butyl, i-butyl and t-butyl); pentyl and its isomers, hexyl and its isomers, etc. A “substituted alkyl” refers to an alkyl group substituted with one or more substituent(s) (for example 1 to 3 substituent(s), for example 1, 2, or 3 substituent(s)) at any available point of attachment.

When the suffix “ene” is used in conjunction with an alkyl group, i.e., “alkylene,” this is intended to mean the alkyl group as defined herein having two single bonds as points of attachment to other groups. As used herein, the term “alkylene” also referred as “alkanediyl,” by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH₂—), ethylene (—CH₂—CH₂—), methylmethylene (—CH(CH₃)—), ₁-methyl-ethylene (—CH(CH₃)—CH₂—), n-propylene (—CH₂—CH₂—CH₂—), ₂-methylpropylene (—CH₂—CH(CH₃)—CH₂—), ₃-methylpropylene (—CH₂—CH₂—CH(CH₃)—), n-butylene (—CH₂—CH₂—CH₂—CH₂—), ₂-methylbutylene (—CH₂—CH(CH₃)—CH₂—CH₂—), ₄-methylbutylene (—CH₂—CH₂—CH₂—CH(CH₃)—), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds. Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C₃₋₂₀alkenyl groups are ethenyl, 2-propenyl, 2-butenyl, 3-butenyl, 2-pentenyl and its isomers, 2-hexenyl and its isomers, 2,4-pentadienyl, and the like.

The term “alkyl halide,” as a group or part of a group, refers to an alkyl group as defined herein above wherein one or more hydrogen atom is substituted for a halogen atom. When a subscript is used herein following a carbon atom, the subscript refers to the number of carbon atoms that the named group may contain. When a subscript is used herein following a fluoro (F), chloro (Cl), bromo (Br), or iodo (I) atom, the subscript refers to the number of fluoro (F), chloro (Cl), bromo (Br), or iodo (I) atoms that the named group may contain.

The term “alkenyl halide,” as a group or part of a group, refers to an alkenyl group as defined herein above wherein one or more hydrogen atom is substituted for a halogen atom. When a subscript is used herein following a carbon atom, the subscript refers to the number of carbon atoms that the named group may contain. When a subscript is used herein following a fluoro (F), chloro (Cl), bromo (Br), or iodo (I) atom, the subscript refers to the number of fluoro (F), chloro (Cl), bromo (Br), or iodo (I) atoms that the named group may contain.

In some embodiments, the one or more carbon reactant may be selected from the group consisting of C₁₋₈alkyl halide and C₂₋₈alkenyl halide. In some embodiments, the one or more carbon reactant may be selected from the group consisting of C₁₋₄alkyl halide and C₂₋₄ alkenyl halide.

In some embodiments, deposition of the dielectric layer comprises the execution of one or more deposition cycles, wherein a cycle comprises a dielectric precursor pulse as described herein, wherein one or more dielectric precursor is transferred from the dielectric precursor vessel to the reaction chamber; and an oxygen reactant pulse as described herein, wherein one or more oxygen reactant is transferred from the oxygen reactant vessel to the reaction chamber.

In some embodiments, the system as disclosed herein provides that the one or more dielectric precursor may comprise one or more element selected from the group consisting of Hf, Zr, Al, Y, Ta, La, Nb, and Ti. The one or more dielectric precursor may further comprise any suitable ligand that enables fast evaporation of the one or more dielectric precursor. For instance, the one or more dielectric precursor may further comprise one or more halogen selected from the group consisting of fluoro (F), chloro (Cl), bromo (Br), iodo (I), and combinations thereof. For instance, the one or more dielectric precursor may further comprise one or more dialkylamine (—NR^{a}R^{b}), wherein Ra and Rb are an alkyl as defined herein, preferably a C₁₋₄alkyl as defined herein.

In some embodiments, the one or more dielectric precursor may be selected from the group consisting of HfCl₄, ZrCl₄, AlCl₃, YCl₃, TaCl₅, LaCl₃, NbCl₅, TiCl₄, HfBr₄, ZrBr₄, AlBr₃, YBr₃, TaBr₅, LaBr₃, NbBr₅, HfI₄, TiBr₄, ZrI₄, AlI₃, YI₃, TaI₅, LaI₃, NbI₅, TiI₄, tetrakis(dimethylamino)hafnium (Hf[N(Me)₂]₄), tetrakis(diethylamino)hafnium (Hf[N(Et)₂]₄), tetrakis(di-n-propylamino)hafnium (Hf[N(Prⁿ) ₂]₄), tetrakis(di-iso-propylamino)hafnium (Hf[N(Prⁱ)₂]₄), tetrakis(di-n-butylamino)hafnium (Hf[N(Buⁿ)₂]₄), tetrakis(di-tert-butylamino)hafnium (Hf[N(Bu^{t}) ₂]⁴), tetrakis(ethylmethylamino)hafnium (Hf[N(Me)(Et)]₄), tetrakis(n-propylmethylamino)hafnium (Hf[N(Me)(Prⁿ)]₄), tetrakis(iso-propylmethylamino)hafnium (Hf[N(Me)(Prⁱ)]₄), tetrakis(n-butylmethylamino)hafnium (Hf[N(Me)(Buⁿ)]₄), tetrakis(tert-butylmethylamino)hafnium (Hf[N(Me)(Bu^{t})]₄), tetrakis(n-propylethylamino)hafnium (Hf[N(Et)(Prⁿ)]₄), tetrakis(iso-propylethylamino)hafnium (Hf[N(Et)(Prⁱ)]₄), tetrakis(n-butylethylamino)hafnium (Hf[N(Et)(Buⁿ)]₄), tetrakis(tert-butylethylamino)hafnium (Hf[N(Et)(Bu^{t})]₄), tetrakis(n-butyl-n-propylamino)hafnium (Hf[N(Prn)(Buⁿ)]₄), tetrakis(tert-butyl-iso-propylamino)hafnium (Hf[N(Prⁱ)(Bu^{t})]₄), and mixtures thereof.

In a particular embodiment, the system as disclosed herein provides that the one or more oxygen reactant may be selected from the group consisting of H₂O, H₂O₂, O₃, O₂, O-containing plasma, N₂O, NO, N₂O₅, and oxygen radicals.

In some embodiments, deposition of the one or more dipole layer comprises the execution of one or more deposition cycles, wherein a cycle comprises a dipole precursor pulse as described herein, wherein one or more dipole precursor is transferred from the dipole precursor vessel to the reaction chamber; and an oxygen reactant pulse as described herein, wherein one or more oxygen reactant is transferred from the oxygen reactant vessel to the reaction chamber.

In a particular embodiment, the system as disclosed herein provides that the one or more dipole precursor may comprise one or more element selected from the group consisting of Sc, Y, Sr, Al, Si, Ga, Ge, In, Sn, La, and Ce. The one or more dipole precursor may further comprise any suitable ligand that enables fast evaporation of the one or more dipole precursor.

In some embodiments, the one or more dipole precursor may be selected from the group consisting of tris(N,N-dimethylacetamidinate)scandium (Sc(MeAMD)₃), tris(N,N-diethylacetamidinate)scandium (Sc(EtAMD)₃), tris(N,N-di-n-propylacetamidinate)scandium (Sc(PrⁿAMD)₃), tris(N,N-di-iso-propylacetamidinate)scandium (Sc(PrⁱAMD)₃), tris(N,N-di-n-butylacetamidinate)scandium (Sc(BuⁿAMD)₃), tris(N,N-di-tert-butylacetamidinate)scandium (Sc(Bu^{t}AMD)₃), tris(methylcyclopentadienyl)scandium (Sc(MeCp)₃), tris(ethylcyclopentadienyl)scandium (Sc(EtCp)₃), tris(n-propylcyclopentadienyl)scandium (Sc(PrⁿCp)₃), tris(iso-propylcyclopentadienyl)scandium (Sc(PrⁱCp)₃), tris(n-butylcyclopentadienyl)scandium (Sc(BuⁿCp)₃), tris(tert-butylcyclopentadienyl)scandium (Sc(Bu^{t}Cp)₃), tris(N,N-dimethylacetamidinate)yttrium (Y(MeAMD)₃), tris(N,N-diethylacetamidinate)yttrium (Y(EtAMD) ₃), tris(N,N-di-n-propylacetamidinate)yttrium (Y(PrⁿAMD)₃), tris(N,N-di-iso-propylacetamidinate)yttrium (Y(PrⁱAMD)₃), tris(N,N-di-n-butylacetamidinate)yttrium (Y(BuⁿAMD)₃), tris(N,N-di-tert-butylacetamidinate)yttrium (Y(Bu^{t}AMD)₃), tris(methylcyclopentadienyl)yttrium (Y(MeCp)₃), tris(ethylcyclopentadienyl)yttrium (Y(EtCp)₃), tris(n-propylcyclopentadienyl)yttrium (Y(PrⁿCp)₃), tris(iso-propylcyclopentadienyl)yttrium (Y(PrⁱCp)₃), tris(n-butylcyclopentadienyl)yttrium (Y(BuⁿCp)₃), tris(tert-butylcyclopentadienyl)yttrium (Y(Bu^{t}Cp)₃), di(N,N-dimethylacetamidinate)strontium (Sr(MeAMD)₂), di(N,N-diethylacetamidinate)strontium (Sr(EtAMD)₂), di(N,N-di-n-propylacetamidinate)strontium (Sr(Pr^{t}AMD)₂), di(N,N-di-iso-propylacetamidinate)strontium (Sr(PrⁱAMD)₂), di(N,N-di-n-butylacetamidinate)strontium (Sr(BuⁿAMD)₂), di(N,N-di-tert-butylacetamidinate)strontium (Sr(Bu^{t}AMD)₂), di(methylcyclopentadienyl)strontium (Sr(MeCp)₂), di(ethylcyclopentadienyl)strontium (Sr(EtCp)₂), di(n-propylcyclopentadienyl)strontium (Sr(PrⁿCp)₂), di(iso-propylcyclopentadienyl)strontium (Sr(PrⁱCp)₂), di(n-butylcyclopentadienyl)strontium (Sr(BuⁿCp)₂), di(tert-butylcyclopentadienyl)strontium (Sr(Bu^{t}Cp)₂), AlCl₃, AlBr₃, AlI₃, AlMe₃, AlEt₃, AlPrⁿ₃, AlPrⁱ₃, AlBuⁿ₃, AlBu^{t}₃, Al(OMe)₃, Al(OEt)₃, Al(OPrⁿ)₃, Al(OPrⁱ)₃, Al(OBuⁿ)₃, Al(OBu^{t})₃, Al(NMe)₃, Al(NEt)₃, Al(NPrⁿ)₃, Al(NPrⁱ)₃, Al(NBuⁿ)₃, Al(NBu^{t})₃, SiCl₄, SiBr₄, SiI₄, SiH₄, Si₂H₆, SiCl₂H₂, SiCl₃H, Si(OMe)₄, Si(OEt)₄, Si(OPrⁿ)₄, Si(OPrⁱ)₄, Si(OBuⁿ)₄, Si(OBu^{t})₄, SiH(NMe)₃, SiH(NEt)₃, SiH(NPrⁿ)₃, SiH(NPrⁱ)₃, SiH(NBuⁿ)₃, SiH(NBu^{t})₃, GaCl₃, GaBr₃, GaI₃, GaMe₃, GaEt₃, GaPrⁿ₃, GaPrⁱ₃, GaBuⁿ₃, GaBu^{t}₃, Ga(acac)₃, Ga₂(NMe₂)₆, GaMe₂NH₂, GaMe₂(OPrⁱ), Ge(OMe)₄, Ge(OEt)₄, Ge(OPrⁿ)₄, Ge(OPrⁱ)₄, Ge(OBuⁿ)₄, Ge(OBu^{t})₄, Ge(NMe₂)₄, (NHPrⁱ(CH₂)₂NHPrⁱ), Ge(NMe₂)₂(NHBu^{t}(CH₂)₂NHBu^{t}), InCl₃, InBr₃, InI₃, InMe₃, InEt₃, InPrⁿ₃, InPrⁱ₃, InBuⁿ₃, InBu^{t}₃, In(acac)₃, tris(N,N-dimethylacetamidinate)indium (In(MeAMD)₃), tris(N,N-diethylacetamidinate) indium (In(EtAMD)₃), tris(N,N-di-n-propylacetamidinate)indium (In(PrⁿAMD)₃), tris(N,N-di-iso-propylacetamidinate)indium (In(PrⁱAMD)₃), tris(N,N-di-n-butylacetamidinate)indium (In(BuⁿAMD)₃), tris(N,N-di-tert-butylacetamidinate)indium (In(Bu^{t}AMD)₃), tris(methylcyclopentadienyl)indium (In(MeCp)₃), tris(ethylcyclopentadienyl)indium (In(EtCp)₃), tris(n-propylcyclopentadienyl)indium (In(PrⁿCp)₃), tris(iso-propylcyclopentadienyl)indium (In(PrⁱCp)₃), tris(n-butylcyclopentadienyl)indium (In(BuⁿCp)₃), tris(tert-butylcyclopentadienyl)indium (In(Bu^{t}Cp)₃), SnCl₄, SnBr₄, SnI₄, SnMe₄, SnEt₄, SnPrⁿ₄, SnPrⁱ₄, SnBuⁿ₄, SnBu^{t}₄, Sn(OMe)₄, Sn(OEt)₄, Sn(OP^{r}n)₄, Sn(OPrⁱ⁾₄, Sn(OBuⁿ)₄, Sn(OBu^{t})₄, Sn(NMe₂)₄, Sn(acac)₂, tris(N,N-dimethylacetamidinate)lanthanum (La(MeAMD)₃), tris(N,N-diethylacetamidinate)lanthanum (La(EtAMD)₃), tris(N,N-di-n-propylacetamidinate)lanthanum (La(PrⁿAMD)₃), tris(N,N-di-iso-propylacetamidinate)lanthanum (La(PrⁱAMD)₃), tris(N,N-di-n-butylacetamidinate)lanthanum (La(BuⁿAMD)₃), tris(N,N-di-tert-butylacetamidinate)lanthanum (La(Bu^{t}AMD)₃), tris(methylcyclopentadienyl)lanthanum (La(MeCp)₃), tris(ethylcyclopentadienyl)lanthanum (La(EtCp)₃), tris(n-propylcyclopentadienyl)lanthanum (La(PrⁿCp)₃), tris(iso-propylcyclopentadienyl)lanthanum (La(PrⁱCp)₃), tris(n-butylcyclopentadienyl)lanthanum (La(BuⁿCp)₃), tris(tert-butylcyclopentadienyl)lanthanum (La(Bu^{t}Cp)₃), tris(N,N-dimethylacetamidinate)cerium (Ce(MeAMD)₃), tris(N,N-diethylacetamidinate)cerium (Ce(EtAMD)₃), tris(N,N-di-n-propylacetamidinate)cerium (Ce(PrⁿAMD)₃), tris(N,N-di-iso-propylacetamidinate)cerium (Ce(PrⁱAMD)₃), tris(N,N-di-n-butylacetamidinate)cerium (Ce(BuⁿAMD)₃), tris(N,N-di-tert-butylacetamidinate)cerium (Ce(Bu^{t}AMD)₃), tris(methylcyclopentadienyl)cerium (Ce(MeCp)₃), tris(ethylcyclopentadienyl)cerium (Ce(EtCp)₃), tris(n-propylcyclopentadienyl)cerium (Ce(PrⁿCp)₃), tris(iso-propylcyclopentadienyl)cerium (Ce(PrⁱCp)₃), tris(n-butylcyclopentadienyl)cerium (Ce(Bu^{t}Cp)₃), tris(tert-butylcyclopentadienyl)cerium (Ce(Bu^{t}Cp)₃), and mixtures thereof.

In some embodiments, transfer of the one or more precursors and/or reactants comprises the evaporation of the one or more precursors and/or reactants. The resulting gas may be optionally mixed with a carrier gas and transported from the respective vessel to the reaction chamber by, for instance, suitable reactor lines. Exemplary carrier gasses include nitrogen (N₂) and a noble gas such as He, Ne, Ar, Xe, or Kr. In some embodiments, the vessels of the system as disclosed herein are temperature-controlled vessels. For instance, the vessels may be maintained at a temperature of at least −50° C. to at most 20° C., or at a temperature of at least 20° C. to at most 250° C., or at a temperature of at least 100° C. to at most 200° C.

Advantageously, it has been found that a controller configured to precisely control the introduction of precursor gas, and reactive gas provides that well-controlled chemical reactions result in more uniform and reproducible thin films or layers. Moreover, the controller may adjust the flow rates and introduction timings to optimize the reaction kinetics, resulting in desired film properties such as a reduction in charge leakage of the formed MIM capacitor, a uniform layer thickness, and controlled composition.

It should be understood that the aforementioned advantages of the herein disclosed method for forming a MIM capacitor equally apply to the system as disclosed herein. In particular, the system may be configured to form MIM capacitors with decreased charge leakages, and defects, resulting in improved memory devices. In some embodiments, the system as disclosed herein is configured to form a metal-insulator-metal (MIM) capacitor by means of a method as disclosed herein.

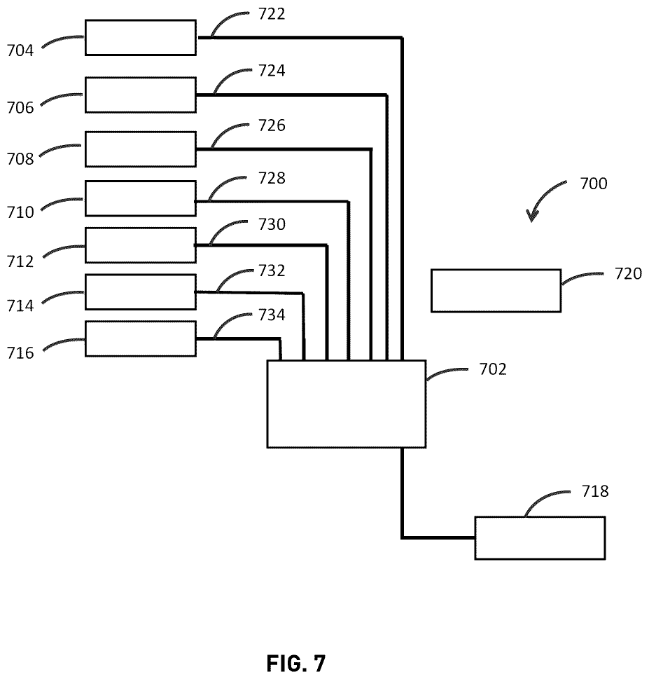

FIG. 7. schematically illustrates an exemplary embodiment of a system (700) as described herein. The system (700) can be used to perform a method as described herein and/or form a MIM capacitor or portion of a memory device as described herein. In the illustrated example, the system (700) includes one or more reaction chambers (702), an electrode precursor gas source (704), a dielectric precursor gas source (706), a dipole precursor gas source (708), a nitrogen reactant gas source (710), a carbon reactant gas source (712), an oxygen reactant gas source (714), a purge gas source (716), an exhaust (718), and a controller (720).

The electrode precursor gas source (704) can include a vessel, and one or more electrode precursors as described herein-alone or mixed with one or more carrier (e.g., inert) gases. The dielectric precursor gas source (706) can include a vessel, and one or more dielectric precursors as described herein-alone or mixed with one or more carrier (e.g., inert) gases. The dipole precursor gas source (708) can include a vessel, and one or more dipole precursors as described herein-alone or mixed with one or more carrier (e.g., inert) gases. The nitrogen reactant gas source (710) can include a vessel, and one or more nitrogen reactants as described herein-alone or mixed with one or more carrier (e.g., inert) gases. The carbon reactant gas source (712) can include a vessel, and one or more carbon reactants as described herein-alone or mixed with one or more carrier (e.g., inert) gases. The oxygen reactant gas source (714) can include a vessel, and one or more oxygen reactants as described herein-alone or mixed with one or more carrier (e.g., inert) gases. The purge gas source (716) can include one or more inert gases such as N₂ or a noble gas, as described herein. The system (700) can include any suitable number of gas sources. The gas sources (704)-(716) can be coupled to reaction chamber (702) via lines (722)-(734), which can each include flow controllers, valves, heaters, and the like. The exhaust (718) can include one or more vacuum pumps.

The controller (720) includes electronic circuitry and software to selectively operate valves, manifolds, heaters, pumps, and other components included in the system (700). Such circuitry and components operate to introduce precursors, reactants, and purge gases from the respective sources (704)-(716). The controller (720) can control timing of gas pulse sequences, temperature of the substrate and/or reaction chamber, pressure within the reaction chamber, and various other operations to provide proper operation of the system (700). The controller (720) can include control software to electrically or pneumatically control valves to control flow of precursors, reactants (i.e., nitrogen reactants and/or oxygen reactants) and purge gases into and out of the reaction chamber (702). The controller (720) can include modules such as a software or hardware component, e.g., a FPGA or ASIC, which performs certain tasks. A module can advantageously be configured to reside on the addressable storage medium of the control system and be configured to execute one or more processes.

Other configurations of the system (700) are possible, including different numbers and kinds of precursor and reactant sources and purge gas sources. Further, it will be appreciated that there are many arrangements of valves, conduits, precursor sources, reactant sources, and purge gas sources that may be used to accomplish the goal of selectively feeding gases into the reaction chamber (702). Further, as a schematic representation of a system, many components have been omitted for simplicity of illustration, and such components may include, for example, various valves, manifolds, purifiers, heaters, containers, vents, and/or bypasses.

During operation of the reactor system (700), substrates, such as semiconductor wafers (not illustrated), are transferred from, e.g., a substrate handling system to reaction chamber (702). Once substrate(s) are transferred to the reaction chamber (702), one or more gases from the gas sources (704)-(716), such as precursors, reactants, carrier gases, and/or purge gases, are introduced into reaction chamber (702).

In addition, embodiments of the controller may include a combination of hardware, software, and electronic components or modules that, for purposes of discussion, may be portrayed as if primarily implemented in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits.

Another aspect of the present disclosure relates to a metal-insulator-metal (MIM) capacitor, comprising: a substrate as described herein; a first conductive layer and a second conductive layer as described herein; a dielectric layer as described herein, arranged between the first conductive layer and the second conductive layer; at least one dipole layer as described herein, wherein the dipole layer is arranged between the first conductive layer and the dielectric layer, or wherein the dipole layer is arranged between the dielectric layer and the second conductive layer, or a combination thereof; and wherein the dielectric layer exhibits a capacitance peak at a characteristic voltage when a variable voltage is applied; wherein the at least one dipole layer is configured to create an asymmetric charge distribution across the dielectric layer, resulting in a shift of the capacitance peak to a target voltage different from the characteristic voltage.

Another aspect of the present disclosure relates to a metal-insulator-metal (MIM) capacitor, comprising: a substrate as described herein; a first conductive layer and a second conductive layer as described herein; a dielectric layer as described herein, arranged between the first conductive layer and the second conductive layer; at least two dipole layers as described herein, wherein at least one first dipole layer is arranged between the first conductive layer and the dielectric layer and at least one second dipole layer is arranged between the dielectric layer and the second conductive layer; and wherein the dielectric layer exhibits a capacitance peak at a characteristic voltage when a variable voltage is applied; wherein the at least two dipole layers are configured to create an asymmetric charge distribution across the dielectric layer, resulting in a shift of the capacitance peak to a target voltage different from the characteristic voltage.

In a particular embodiment, the MIM capacitor is formed by means of a method as disclosed herein. Preferably, the MIM capacitor is formed in a system as disclosed herein. It should be noted that any embodiments of the method as disclosed herein or the system as disclosed herein also form embodiments of the MIM capacitor as disclosed herein, and vice versa.

In a particular embodiment, the MIM capacitor as disclosed herein provides that the first dipole layer arranged between the first conductive layer and the dielectric layer may be an n-type dipole layer; and the second dipole layer arranged between the dielectric layer and the second conductive layer may be a p-type dipole layer. In a particular embodiment, the first dipole layer arranged between the first conductive layer and the dielectric layer may be a p-type dipole layer; and the second dipole layer arranged between the dielectric layer and the second conductive layer may be an n-type dipole layer.

In a particular embodiment, the MIM capacitor as disclosed herein provides that at least one dipole layer is formed, preferably including the first dipole layer or the second dipole layer as defined herein, which may shift the capacitance peak of the dielectric layer to a target voltage by at least 10 mV, or at least 15 mV, or at least 30 mV, or at least 50 mV, or at least 100mV, or at least 200 mV, or at least 500 mV.

In a particular embodiment, the MIM capacitor as disclosed herein provides that at least two dipole layers are formed, preferably including the first dipole layer and the second dipole layer as defined herein, which may shifts the capacitance peak of the dielectric layer to a target voltage by at least 10 mV, or at least 15 mV, or at least 30 mV, or at least 50 mV, or at least 100 mV, or at least 200 mV, or at least 500 mV. Advantageously, the use of at least two dipole layers can provide a larger shift in capacitance peak of the dielectric layer, when compared to using one dipole layer.

Advantageously, the herein disclosed MIM capacitor can be regarded as a general-purpose technology in the sense that it can be readily adapted for a variety of electronic devices and systems, including but not limited to computers, consumer electronics, communication devices, automotive systems, and industrial control systems.

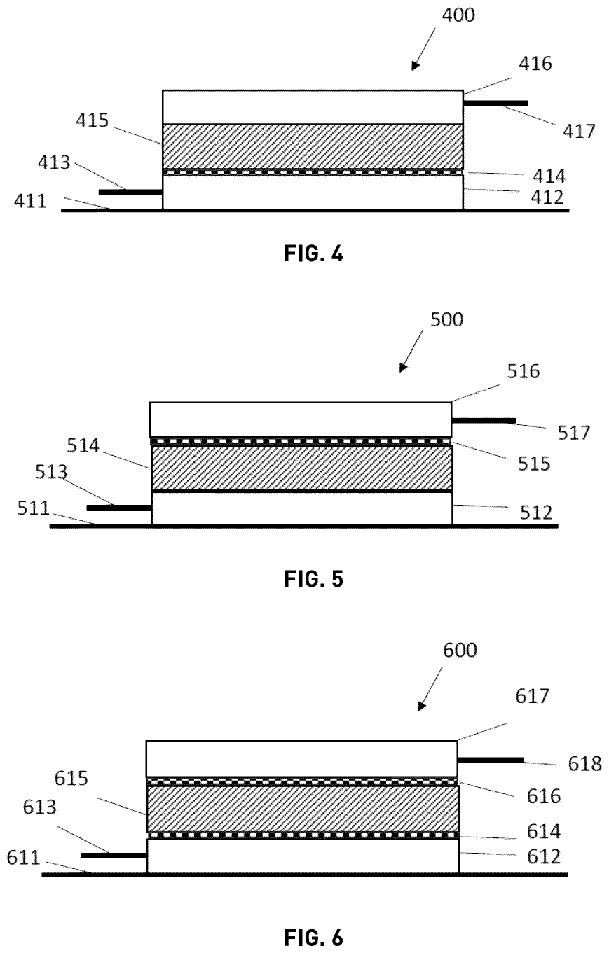

FIG. 4. schematically illustrates an exemplary MIM capacitor (400) of the present disclosure. The MIM capacitor (400) may be manufactured using a method and/or system as disclosed herein such as the method of FIG. 1. In the illustrated example, the MIM capacitor (400) includes a first conductive or electrode layer (412) and a second conductive or electrode layer (416), separated by a dielectric or insulator layer (415) and a dipole layer (414) arranged between the first conductive layer (412) and the dielectric layer (415).

The MIM capacitor (400) further comprises a substrate (411) holding the conductive layers (412, 416), the dipole layer (414), and the dielectric layer (415). The dielectric layer (415) may optionally be doped with a dopant as described herein. The MIM capacitor (400) further comprises two contacts or electrical connections (413,417) to the conductive layers. Given that this is a schematic representation of a MIM capacitor, certain components may have been omitted for clarity of illustration.

FIG. 5. schematically illustrates an exemplary MIM capacitor (500) of the disclosure. The MIM capacitor (500) may be manufactured using a method and/or system as disclosed herein such as the method of FIG. 2. In the illustrated example, the MIM capacitor (500) includes a first conductive or electrode layer (512) and a second conductive or electrode layer (516), separated by a dielectric or insulator layer (514) and a dipole layer (515) arranged between the dielectric layer (514) and the second conductive layer (516).

The MIM capacitor (500) further comprises a substrate (511) holding the conductive layers (512, 516), the dipole layer (515), and the dielectric layer (514). The dielectric layer (514) may optionally be doped with a dopant as described herein. The MIM capacitor (500) further comprises two contacts or electrical connections (513,517) to the conductive layers. Given that this is a schematic representation of a MIM capacitor, certain components may have been omitted for clarity of illustration.

FIG. 6. schematically illustrates an exemplary MIM capacitor (600) of the disclosure. The MIM capacitor (600) may be manufactured using a method and/or system as disclosed herein such as the method of FIG. 3. In the illustrated example, the MIM capacitor (600) includes a first conductive or electrode layer (612) and a second conductive or electrode layer (617), separated by a dielectric or insulator layer (615), a dipole layer (614) arranged between the first conductive layer (612) and the dielectric layer (615), and a dipole layer (616) arranged between the dielectric layer (615) and the second conductive layer (617).

The MIM capacitor (600) further comprises a substrate (611) holding the conductive layers (612, 617), the dipole layers (614, 616), and the dielectric layer (615). The dielectric layer (615) may optionally be doped with a dopant as described herein. The MIM capacitor (600) further comprises two contacts or electrical connections (613,618) to the conductive layers. Given that this is a schematic representation of a MIM capacitor, certain components may have been omitted for clarity of illustration.

In some embodiments, the present disclosure relates to a memory device comprising: a substrate; a memory cell formed over the substrate, the memory cell comprising a transistor including a gate fabricated on the substrate, and source and drain regions in the substrate disposed adjacent to the gate; a charge storage metal-insulator-metal (MIM) capacitor electrically connected to one of the source and drain regions, the capacitor comprising a substrate; a first conductive layer and a second conductive layer; a dielectric layer, arranged between the first conductive layer and the second conductive layer; at least one dipole layer, arranged between the first conductive layer and the dielectric layer, or between the dielectric layer and the second conductive layer, or a combination thereof; and wherein the dielectric layer exhibits a capacitance peak at a characteristic voltage when a variable voltage is applied; wherein the at least one dipole layer is configured to create an asymmetric charge distribution across the dielectric layer, resulting in a shift of the capacitance peak to a voltage different from the characteristic voltage.

In a particular embodiment, the memory device as disclosed herein provides that the charge storage metal-insulator-metal (MIM) capacitor is formed by means of a method as disclosed herein. Preferably, wherein the charge storage metal-insulator-metal (MIM) capacitor is formed in a system as disclosed herein.

The subject matter of the present disclosure includes all novel and nonobvious combinations and subcombinations of the various processes, systems, and configurations, and other features, functions, acts, and/or properties disclosed herein, as well as any and all equivalents thereof.

As an exemplary embodiment, the method as disclosed herein may be performed using a system according to FIG. 7 as described herein. According to the embodiment, the method starts by providing a silicon substrate to a reaction chamber. Next, a conductive layer comprising TiN is deposited on at least a part of the silicon substrate. A p-type dipole layer comprising Al2O3 is subsequently formed on the TiN conductive layer, followed by the deposition of a dielectric layer comprising HfZrO₂ (HZO). Next, an n-type dipole layer comprising La₂O₃ is formed on the dielectric layer, followed by the deposition of a TiN conductive layer. The resulting stack of layers is suitable for forming a MIM capacitor as disclosed herein. By applying a variable voltage to the dielectric layer, it was found that the capacitance peak of the dielectric layer could be shifted with 0.3V, for example.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

What is claimed:

1. A method for manufacturing a metal-insulator-metal (MIM) capacitor, comprising the steps of:
a) providing a substrate to a reaction chamber;
b) forming a first conductive layer on at least a part of the substrate;
c) optionally, forming a first dipole layer on the first conductive layer;
d) forming a dielectric layer on the first conductive layer or on the optional first dipole layer; wherein the dielectric layer exhibits a capacitance peak at a characteristic voltage when a variable voltage is applied;
e) optionally, forming a second dipole layer on the dielectric layer; and
f) forming a second conductive layer on the dielectric layer or on the optional second dipole layer, provided that at least the first dipole layer and/or the second dipole layer are formed,
wherein at least one of the first dipole layer and/or the second dipole layer is configured to create an asymmetric charge distribution across the dielectric layer, resulting in a shift of the capacitance peak of the dielectric layer to a target voltage different from said characteristic voltage.

2. The method according to claim 1, wherein the first dipole layer and the second dipole layer each independently comprise an element selected from the group consisting of Sc, Y, Sr, Al, Si, Ga, Ge, In, Sn, La, and Ce.

3. The method according to claim 1, wherein the first dipole layer and the second dipole layer each independently comprise an oxide selected from the group consisting of Sc₂0₃, Y₂O₃, SrO, Al₂O₃, SiO₂, Ga₂O₃, GeO₂, In₂O₃, SnO₂, La₂O₃, and CeO₂.

4. The method according to claim 1, wherein the first dipole layer is an n-type dipole layer, and the second dipole layer is a p-type dipole layer.

5. The method according to claim 1, wherein the first dipole layer is a p-type dipole layer, and the second dipole layer is an n-type dipole layer.

6. The method according to claim 1, wherein the at least one of the first dipole layer and the second dipole layer has a dielectric constant (k) value of at least 15.0.

7. The method according to claim 1, wherein the dielectric layer comprises a high k dielectric material with a dielectric constant (k) value of at 20.0.

8. The method according to claim 7, wherein the high k dielectric material comprises one or more oxides.

9. The method according to claim 8, wherein the one or more oxides is selected from the group consisting of hafnium zirconium oxide (HfZrO₂), aluminum oxide (Al₂O₃), yttrium oxide (Y₂O₃), tantalum oxide (Ta₂O₅), hafnium oxide (HfO₂), zirconium oxide (ZrO₂), lanthanum oxide (La₂O₃), niobium oxide (Nb₂O₅), and titanium oxide (TiO₂).

10. The method according to claim 1, wherein the dielectric layer comprises a dopant selected from the group consisting of PH₃, PF₅, PCl₅, PBr₅, AsF₅, AsCl₅, AsBr₅, AsH₃, SbF₃, SbCl₃, SbBr₃, BF₃, BCl₃, BBr₃, B₂H₆, AlF₃, AlCl₃, AlBr₃, InF₃, InCl₃, and InBr₃.

11. The method according to claim 1, wherein at least one of the first dipole layer and the second dipole layer results in a shift of the capacitance peak of the dielectric layer to a target voltage of at least 10 mV.

12. The method according to claim 1, wherein the first dipole layer and the second dipole layer each independently have an average thickness of at least 0.01 nm to at most 2.0 nm, or at least 0.01 nm to at most 1.0 nm, preferably at least 0.01 nm to at most 0.5 nm, more preferably at least 0.01 nm to at most 0.1 nm.

13. The method according to claim 1, wherein the method is an atomic layer deposition (ALD) method.

14. A system comprising:
a reaction chamber constructed and arranged to hold a substrate;
an electrode precursor vessel constructed and arranged to contain and evaporate one or more electrode precursors;
a dipole precursor vessel constructed and arranged to contain and evaporate one or more dipole precursors;
a dielectric precursor vessel constructed and arranged to contain and evaporate one or more dielectric precursors;
an oxygen reactant vessel constructed and arranged to contain and evaporate one or more oxygen reactants;
a nitrogen reactant vessel constructed and arranged to contain and evaporate one or more nitrogen reactants;
a carbon reactant vessel constructed and arranged to contain and evaporate one or more carbon reactants; and
a controller, operatively connected to the electrode precursor vessel, the dipole precursor vessel, the dielectric precursor vessel, the oxygen reactant vessel, the nitrogen reactant vessel, and the carbon reactant vessel,
wherein the controller is configured to control the introduction of the one or more electrode precursors, the one or more dipole precursors, the one or more dielectric precursors, the one or more oxygen reactants, the one or more nitrogen reactants, and the one or more carbon reactants, into the reaction chamber during one or more cycles, wherein, as a result of the cycles, a metal-insulator-metal (MIM) capacitor is formed comprising a dielectric layer with a capacitance peak at a characteristic voltage when a variable voltage is applied; and wherein the MIM capacitor further comprises at least one dipole layer configured to create an asymmetric charge distribution across the dielectric layer, resulting in a shift of the capacitance peak to a target voltage different from the characteristic voltage.

15. The system according to claim 14, wherein the one or more electrode precursor comprises one or more element selected from the group consisting of Mg, Ca, Cu, Sr, Ba, Al, Ga, In, Sc, Y, La, Ce, Pr, Nd, Pm, Sm, Eu, Gd, Tb, Dy, Ho, Er, Tm, Yb, Lu, Ti, Zr, Hf, V, Nb, Ta, Cr, Mo, Re, Ge, Sb, Zn, and W.

16. The system according to claim 14, wherein the one or more dipole precursor comprises one or more element selected from the group consisting of Sc, Y, Sr, Al, Si, Ga, Ge, In, Sn, La, and Ce.

17. The system according to claim 14, wherein the one or more dielectric precursor comprises one or more element selected from the group consisting of Hf, Zr, Al, Y, Ta, La, Nb, and Ti.

18. The system according to claim 14, wherein the one or more oxygen reactant is selected from the group consisting of H₂O, H₂O₂, O₃, O₂, O-containing plasma, N₂O, NO, N₂O₅, and oxygen radicals.

19. The system according to claim 14, wherein the one or more nitrogen reactant is selected from the group consisting of ammonia (NH₃), diazene (N₂H₂), and hydrazine (N₂H₄).

20. The system according to claim 14, wherein the one or more carbon reactant is selected from the group consisting of alkyl halide and alkenyl halide.
